(19) United States
(12) Patent Application Publication
(10) Pub. No.: US 2009/0151765 A1
(43) Pub. Date: Jun. 18, 2009

(54) ASSISTANT POWER SUPPLY UNIT, POWER SUPPLIER HAVING ASSISTANT POWER SUPPLY UNIT, ELECTRONIC DEVICE HAVING POWER SUPPLY UNIT, AND METHOD OF OPERATING ELECTRONIC DEVICE USING POWER SUPPLIER IN POWER-SAVING MODE

(75) Inventors: Jae-uk HAN, Osan-si (KR); Kwang-youn SEO, Suwon-si (KR); Kyung-rah AHN, Suwon-si (KR)

Correspondence Address: STEIN MCEWEN, LLP, 1400 EYE STREET, NW, SUITE 300, WASHINGTON, DC, 20005, US

(73) Assignee: SAMSUNG ELECTRONICS CO., LTD., Suwon-si (KR)

(21) Appl. No.: 12/196,789

(22) Filed: Aug. 22, 2008

(30) Foreign Application Priority Data
Dec. 12, 2007 (KR) 2007-129083

(51) Int. Cl. H01L 35/34; H01L 35/00

(52) U.S. Cl. 136/201; 136/207

(57) ABSTRACT

Provided are, a power supplier including an assistant power supply unit, an electronic device including the power supplier, and a method of operating the electronic device using the power supplier in a power-saving mode. The assistant power supply unit includes: a heat source to generate heat during operation of the electronic device; a cooler to dissipate the heat generated by the heat source; a thermoelectric generator interposed between the heat source and the cooler; and a secondary battery to store power generated by the thermoelectric generator.

### CROSS-REFERENCE TO RELATED APPLICATION

This application claims the benefit of Korean Patent Application No. 2007-129083, filed Dec. 12, 2007 in the Korean Intellectual Property Office, the disclosure of which is incorporated herein by reference.

### BACKGROUND OF THE INVENTION

1. Field of the Invention

Aspects of the present invention relate to a power supplier of an electronic device, and more particularly, to an assistant power supply unit, which generates and stores power using waste heat, a power supplier having the assistant power supply unit, an electronic device having the power supplier, and a method of operating the electronic device using the power supplier in a power-saving mode.

2. Description of the Related Art

Electronic devices, such as computers, notebook computers, televisions (TVs), and portable multimedia players (PMPs), consume electrical energy to perform functions in response to users' instructions. An electronic device includes electronic components, such as a central processing unit (CPU) and a chipset. The electronic components generate a large amount of waste heat during operation of the electronic device, thereby worsening the energy efficiency of the electronic device. When the waste heat is not properly dissipated, malfunctions and faults may occur in the electronic device. Also, due to the ever-increasing cost of energy, electronic device having higher energy efficiencies are in high demand.

### SUMMARY OF THE INVENTION

Aspects of the present invention provide an assistant power supply unit, which produces electrical energy using waste heat generated by electronic components of an electronic device, a power supplier including the assistant power supply unit, and a method of operating the electronic device using the power supplier in a power-saving mode.

According to an aspect of the present invention, there is provided an assistant power supply unit including at least one waste heat recycler, and a secondary battery to store power generated by the waste heat recycler. The waste heat recycler includes: a thermoelectric generator; heat source to heat one side of the thermoelectric generator, during the operation of an electronic device; and a cooler to cool a second side of the thermoelectric generator.

According to another aspect of the present invention, there is provided a power supplier including: a main power supply unit to supply power to a function unit that performs operations of an electronic device; an assistant power supply unit to supply power to the function unit when the function unit is in a standby mode; and a switching unit to selectively connect the main power supply unit and the assistant power supply unit to the function unit.

According to another aspect of the present invention, there is provided an electronic device including: a function unit to perform predetermined operations; and a power supplier to supply power to the function unit.

According to still another aspect of the present invention, there is provided a method of operating an electronic device in a power-saving mode. The electronic device includes a function unit, which performs predetermined operations, and a power supplier, which includes a main power supply unit and an assistant power supply unit. The method includes: supplying power to the function unit using the main power supply unit, when the function unit performs the operations; and supplying power to the function unit using the assistant power supply unit, when the function unit enters a stand-by mode. The supplying of power to the function unit using the assistant power supply unit includes: generating power by using a waste heat recycler; storing the power in a secondary battery; and supplying the stored power to the function unit. The waste heat recycler includes a thermoelectric generator, a heat source to heat a first side of the thermoelectric generator during the operation of the electronic device, and a cooler to cool a second side of the thermoelectric generator.

The assistant power supply unit may further include a rectifier to convert an AC power produced by the thermoelectric generator into a DC power that is stored in the secondary battery.

According to an aspect of the present invention, the heat source may be selected from the group consisting of a central processing unit (CPU), a graphics processing unit (GPU), and a chipset, of the electronic device.

According to an aspect of the present invention, the cooler may be a fan, a heat sink, or a combination thereof.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the exemplary embodiments, taken in conjunction with the accompanying drawings, of which:

FIG. 1 is a block diagram of an electronic device, according to an exemplary embodiment of the present invention;

FIG. 2 is a view showing the construction of an assistant power supply unit shown in FIG. 1; and

FIG. 3 is a flowchart of a method of operating an electronic device in a power-saving mode, according to an exemplary embodiment of the present invention.

### DETAILED DESCRIPTION OF THE EXEMPLARY EMBODIMENTS

Reference will now be made in detail to the exemplary embodiments of the present invention, examples of which are illustrated in the accompanying drawings, wherein like reference numerals refer to the like elements throughout. The exemplary embodiments are described below, in order to explain the present invention by referring to the figures.

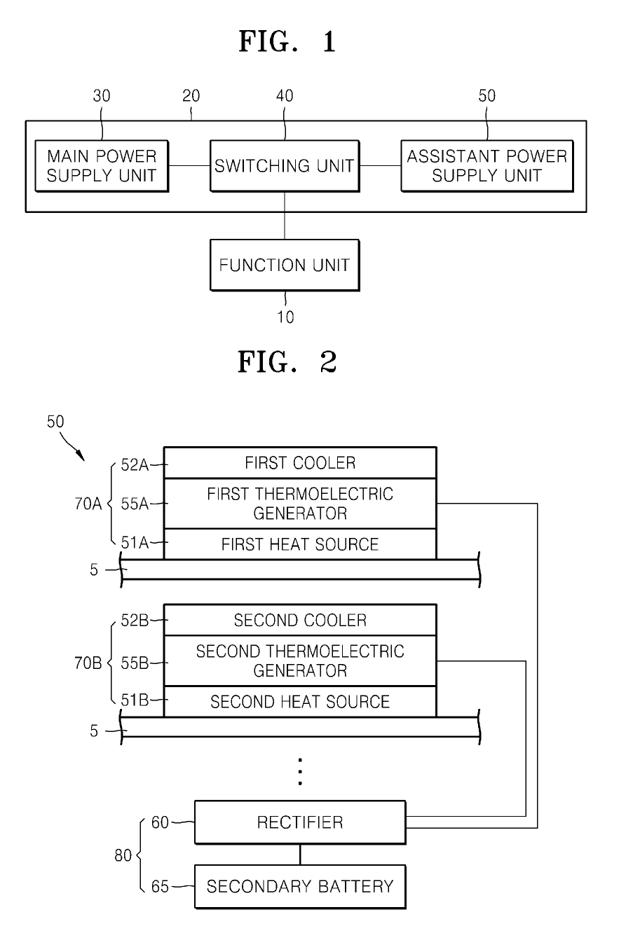

FIG. 1 is a block diagram of an electronic device, according to an exemplary embodiment of the present invention. Referring to FIG. 1, the electronic device includes a function unit 10, which performs predetermined functions of the electronic device, and a power supplier 20, which supplies power to the function unit 10. The electronic device may be, but is not limited to, a computer, a notebook computer, a television (TV), a telephone, a video game system, a portable multimedia player (PMP), or other like device. The predetermined functions may be functions performed by the electronic device. For example, a computer or a notebook computer performs specific functions in response to instructions input by a user using software, and a TV outputs images via a display panel, and the PMP records and/or reproduces audio and/or video data.

The power supplier 20 includes a main power supply unit 30, an assistant power supply unit 50, and a switching unit 40. The main power supply unit 30 supplies power to the function unit 10, which perform functions of the electronic device. The assistant power supply unit 50 supplies power to the function unit 10, when the function unit 10 is in a standby mode. The switching unit 40 selectively connects the function unit 10 to the main power supply unit 30 or the assistant power supply unit 50, according to whether the function unit 10 is in an operating mode or a standby mode. In particular, the switching unit 40 connects the assistant power supply unit 50 to the function unit 10, when the function unit 10 is in the standby mode.

The main power supply unit 30 may be connected an external power source, such as a power grid. The power received via the power grid may be directly supplied to the function unit 10 or may be stored and then supplied to the function unit 10. However, the main power supply unit 30 is not limited to the above description, and can be a secondary battery or a fuel cell in addition to, or instead of, a plug connection to the external power source.

FIG. 2 is a view showing the construction of the assistant power supply unit 50. Referring to FIG. 2, the assistant power supply unit 50 includes: a first waste heat recycler 70A, a second waste heat recycler 70B, and a power storage unit 80. The first waste heat recycler 70A includes a first heat source 51A, which generates waste heat during operation of the electronic device; a first cooler 52A, which dissipates the heat generated by the first heat source 51A; and a first thermoelectric generator 55A, which is interposed between the first heat source 51A and the first cooler 52A. The second waste heat recycler 70B includes a second cooler 52B, a second heat source 51B, and a second thermoelectric generator 55B disposed therebetween.

The power storage unit 80 includes a secondary battery 65, which stores power generated by the thermoelectric generators 55A and 55B, and a rectifier 60, which rectifies the power generated by the thermoelectric generators 55A and 55B and supplies the rectified voltage to the secondary battery 65. Although FIG. 2 illustrates two waste heat recyclers 70 and 72, the present invention is not limited to any particular number of waste heat recyclers or power storage units. While not required, multiple heat sources can be cooled by a common recycler.

During the operation of the electronic device, the waste heat is generated by various electronic components of the electronic device. Any electronic component that generates the waste heat may be one of the heat sources 51A and 51B. For example, a central processing unit (CPU), a graphics processing unit (GPU), or a chipset (e.g., a north bridge or a south bridge), can be used as a heat source. Such a heat source can be mounted on a circuit substrate 5 included in the electronic device. Each of the coolers 52A and 52B may be, for example, a fan, a heat sink, or a combination thereof. For example, the heat sink can be formed of a metal with a high thermal conductivity. However, the present invention is not limited to the above-described examples of the heat sources 51A and 51B and the coolers 52A and 52B.

Each of the thermoelectric generators 55A and 55B induces an electro motive force (EMF) (alternating current), due to a temperature difference, according to the Seebeck effect, also referred to as the Peltier-Seebeck effect. Waste heat generated by the heat sources 51A and 51B is transmitted through the corresponding thermoelectric generators 55A and 55B to the coolers 52A and 52B, where it is dissipated. In order to accelerate the transmission of the waste heat from the heat sources 51A and 51B to the coolers 52A and 52B, a thermal grease, a thermal tape, or a thermal pad (not shown) may be interposed between the heat sources 51A and 51B and the thermoelectric generators 55A and 55B, and/or between the thermoelectric generators 55A and 55B and the coolers 52A and 52B. The heat sources 51A and 51B, the thermoelectric generators 55A and 55B, and the coolers 52A and 52B may be adhered to one another, or may be disposed on different parts of a same or a different substrate.

When the electronic device is turned on, the heat sources 51A and 51B (e.g., the CPU, the GPU, and/or the chipset) generate the waste heat, thereby causing temperature differences in contact areas between the heat sources 51A and 51B and the thermoelectric generators 55A and 55B, and contact areas between the thermoelectric generators 55A and 55B and the coolers 52A and 52B. Due to the temperature differences, the thermoelectric generators 55A and 55B generate an alternating current. The alternating current is converted by the rectifier 60 into a direct current and then stored in the secondary battery 65. The thermoelectric generators 55A and 55B can be formed of any thermoelectric material having good thermopower properties.

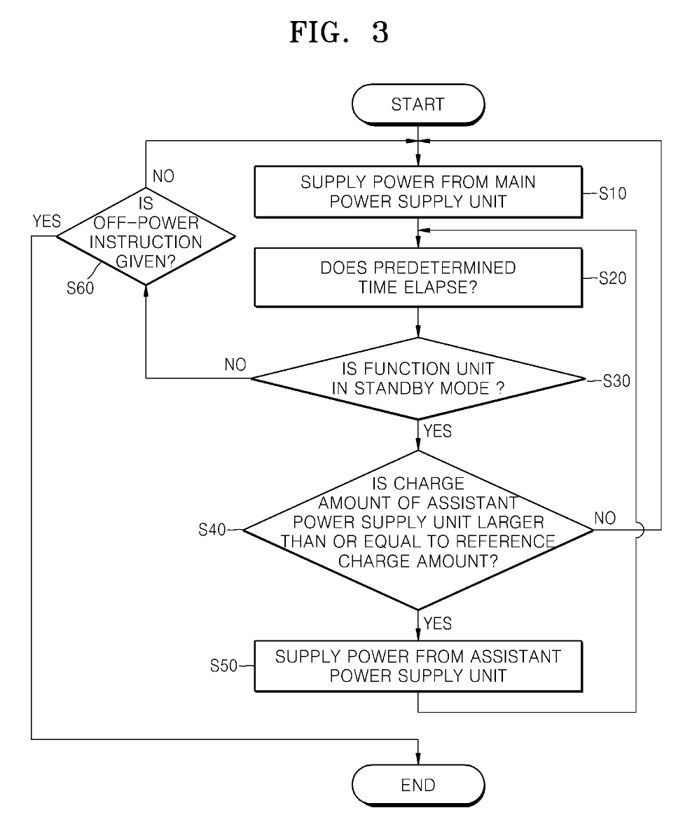

Hereinafter, a method of operating an electronic device in a power-saving mode (standby mode), according to an exemplary embodiment of the present invention, will be described with reference to FIGS. 1 and 3. However, the method of the present invention is not limited to the following description.

Referring to FIGS. 1 and 3, in operation S10, when the electronic device is turned on, the main power supply unit 30 is used to supply an operating power to the function unit 10. Instructions are input via an instruction input portion of the electronic device. When the function unit 10 performs specific operations, i.e., is in an operating mode, in response to the instructions, the main power supply unit 10 supplies the operating power to the function unit 10. When the function unit 10 is not performing an operation, the function unit 10 can enter the standby mode. When in standby mode, the function unit 10 generally has lower power requirements than when performing operations.

In operations S20 and S30, a determination is made, at predetermined time intervals, as to whether the main power supply unit 30 is in the operating mode, or is in the standby mode. The determination can be repeatedly performed, and the time intervals can be, for example, 1 second, 2 seconds, 5 seconds, or the like. If it is determined that the function unit 10 is in the standby mode, the method proceeds to operation S40, if not, the method proceeds to operation S60.

In operation S40, the charge amount of the secondary battery 65 is compared to a reference charge amount. The reference charge amount corresponds to an amount of power used by the electronic device when in the standby mode. If the charge amount of the secondary battery 65 is larger than the reference charge amount, the method proceeds to operation S50. If not, the method returns to operation S10.

In operation S50, the switching unit 40 disconnects the main power supply unit 30 from the function unit 10 and connects the assistant power supply unit 50 to the function unit 10. In other words, the switching unit 40 allows the assistant power supply unit 50 to supply the standby power to the function unit 10. The standby power is generated by the waste heat recyclers 70A and 70B, during operating of the electronic device (i.e., operation S10), and is then stored in the secondary battery 65. The method then returns to operation S20.

If the method returns to operation S10, the main power supply unit 30 is used to supply the operating power to the function unit 10. This occurs even if the function unit 10 is in the standby mode.

In operation S60, it is determined whether a power-off instruction is given. If no power-off instruction is detected, the method returns to operation S10, and the main power supply unit 30 is used to supply power to the function unit 10. If the assistant power supply unit 50 is being used to supply power to the function unit 10, the switching unit 40 connects the main power supply unit 30 to the function unit 10, such that the operating power is supplied to the function unit 10. If it is determined that the power-off instruction is given in operation S60, no power is supplied to the functioning unit 10, and electronic device is powered down.

According to aspects of the present invention, power is produced using waste heat generated by electronic components of an electronic device, and the power is used to operate the electronic device in a standby mode, thereby reducing the power consumption of the electronic device. In particular, when the electronic device is in standby mode, the power produced using the waste heat can be to operate the electronic device, so that the electronic device does not require externally supplied power. While not required, aspects of the present invention can be implemented using computer software and/or firmware encoded on a computer readable medium and executed by one or more processors.

Although a few exemplary embodiments of the present invention have been shown and described, it would be appreciated by those skilled in the art that changes may be made in these embodiments, without departing from the principles and spirit of the invention, the scope of which is defined in the claims and their equivalents.

What is claimed is:

1. An assistant power supply unit comprising:
a waste heat recycler comprising:
a thermoelectric generator to generate power using waste heat;
a heat source that generates the waste heat during the operation of an electronic device, to heat a first side of the thermoelectric generator; and
a cooler to cool a second side of the thermoelectric generator; and
a secondary battery to store the power generated by the thermoelectric generator.

2. The assistant power supply unit of claim 1, further comprising a rectifier to rectify the power before the power is stored in the secondary battery.

3. The assistant power supply unit of claim 1, wherein the heat source comprises a central processing unit (CPU), a graphics processing unit (GPU), or a chipset, of the electronic device.

4. The assistant power supply unit of claim 1, wherein the cooler comprises a fan, a heat sink, or a combination thereof.

5. A power supplier comprising:
a main power supply unit to supply an operating power to a function unit of an electronic device;
an assistant power supply unit to supply a standby power to the function unit, the assistant power supply comprising:
a waste heat recycler comprising:
a thermoelectric generator to generate the standby power using waste heat;
a heat source that generates the waste heat during operations of the electronic device, to heat a first side of the thermoelectric generator; and
a cooler to cool a second side of the thermoelectric generator; and
a secondary battery to store the standby power generated by the thermoelectric generator; and
a switching unit to connect the main power supply unit to the function unit, when the function unit is performing operations of the electronic device, and to connect the assistant power supply unit to the function unit, when the function unit is not performing the operation.

6. The power supplier of claim 5, wherein the assistant power supply unit further comprises a rectifier to rectify the standby power generated by the waste heat recycler, before the standby power is stored in the secondary battery.

7. The power supplier of claim 5, wherein the heat source comprises a central processing unit (CPU), a graphics processing unit (GPU), or a chipset, of the electronic device.

8. The power supplier of claim 5, wherein the cooler comprises a fan, a heat sink, or a combination thereof.

9. An electronic device comprising:
a function unit to perform an operation of the electronic device;
a main power supply unit to supply an operating power to the function unit;
an assistant power supply unit to supply a standby power to the function unit, the assistant power supply comprising:
a waste heat recycler comprising:
a thermoelectric generator to generate the standby power using waste heat;
a heat source that generates the waste heat during operations of the electronic device, to heat a first side of the thermoelectric generator; and
a cooler to cool a second side of the thermoelectric generator; and
a secondary battery to store the standby power generated by the thermoelectric generator; and
a switching unit to connect the main power supply unit to the function unit, when the function unit performs the operation, and to connect the assistant power supply unit to the function unit, when the function unit is not performing the operation.

10. The device of claim 9, wherein the assistant power supply unit further comprises a rectifier to rectify the standby power before the standby power is stored in the secondary battery.

11. The device of claim 9, wherein the heat source comprises a central processing unit (CPU), a graphics processing unit (GPU), or a chipset, of the function unit.

12. The device of claim 9, wherein the cooler is a fan, a heat sink, or a combination thereof.

13. A method of operating an electronic device comprising a function unit to perform an operation of the electronic device, a main power supply unit to supply an operating power to the function unit, and an assistant power supply unit to supply a standby power to the function unit, the method comprising:
supplying the operating power to the function unit, when the function unit performs the operation;
generating the standby power using a waste heat recycler comprising a thermoelectric generator that generates the standby power using waste heat, a heat source of the electronic device, which generates the waste heat during the operation of the electronic device and supplies the waste heat to the thermoelectric generator, and a cooler to dissipate the waste heat from the thermoelectric generator;
storing the generated standby power in a secondary battery; and
supplying the stored standby power from the secondary battery to the function unit, when the function unit enters a stand-by mode.

14. The method of claim 13, wherein the storing of the standby power comprises rectifying the standby power prior to the storing of the standby power in the secondary battery.

15. The method of claim 13, wherein the heat source comprises a central processing unit (CPU), a graphics processing unit (GPU), or a chipset, of the electronic device.

16. The method of claim 13, wherein the cooler comprises a fan, a metal heat sink, or a combination thereof.

17. The assistant power supply unit of claim 1, further comprising a plurality of the waste heat recyclers to generate the power, each of the waste heat recyclers corresponding to a different element of the electronic device.

18. The power supplier of claim 5, further comprising a plurality of the waste heat recyclers to generate the standby power, each of the waste heat recyclers corresponding to a different element of the electronic device.

19. The method of claim 13, wherein the generating of the standby power comprises using a plurality of the waste heat recyclers to generate the standby power, each of the waste heat recyclers corresponding to a different element of the electronic device.

20. The assistant power supply unit of claim 17, wherein the plurality of waste heat recyclers are disposed on a common substrate.

21. The assistant power supply unit of claim 1, wherein the thermoelectric generator generates the power, due to the Seebeck effect.

22. An assistant power supply comprising:
an electronic component that generates waste heat;
a cooler to dissipate the waste heat;
a thermoelectric generator disposed between the cooler and the electronic component, to generate power using the waste heat from the electronic component, due to the Seebeck effect; and
a secondary battery to store the power generated by the thermoelectric generator.

23. The assistant power supply of claim 22, wherein the secondary battery supplies the power to the electronic component, when the electronic component enters a standby mode.

24. The assistant power supply of claim 22, further comprising a rectifier to rectify the power before the power is stored in the secondary battery.
